(19) United States
(12) Patent Application Publication
(10) Pub. No.: US 2026/0107749 A1
(43) Pub. Date: Apr. 16, 2026

(54) SUPERCONFORMAL MOLYBDENUM VIA FILL BY USE OF DEPOSITION GRADIENT CONTROL

(71) Applicant: Applied Materials, Inc., Santa Clara, CA (US)

(72) Inventors: Jiajie CEN, Santa Clara, CA (US); Wenting HOU, Sunnyvale, CA (US); Shiyu YUE, Santa Clara, CA (US); Shiyu HU, Cupertino, CA (US); Ruinan ZHOU, Santa Clara, CA (US); Rongjun WANG, Dublin, CA (US); Xianmin TANG, San Jose, CA (US)

(21) Appl. No.: 18/916,446

(22) Filed: Oct. 15, 2024

(51) Int. Cl. H01L 21/768; C23C 16/02

(52) U.S. Cl. CPC H10W 20/056; C23C 16/0281; H10W 20/033

(57) ABSTRACT

The present disclosure provides metal gap fill deposition methods on a semiconductor substrate. The methods include forming a liner layer on a surface of a feature by providing a first dosage and a second dosage of a first metal-containing precursor to a processing chamber. The feature includes a feature formed in a surface of the semiconductor substrate. The feature includes an opening that is defined by a capping layer and side walls. The side walls include a dielectric material. The liner layer is formed over the side walls and the capping layer. A metal gap fill material is deposited over the liner layer to fill the feature formed in the surface of the semiconductor substrate by providing a second metal-containing precursor and a hydrogen-containing precursor to the processing chamber.

### BACKGROUND

### Field

Embodiments of the present invention generally relate to gap fill deposition. More specifically, embodiments of the present disclosure relate to apparatus and methods for depositing a molybdenum containing layer.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

In a traditional interconnect formation process, a feature also referred to a cavity, a via, or a trench, is fabricated in the semiconductor substrate. Interconnects allow electrical connections to be formed between layers of an integrated circuit containing device. A low resistivity interconnect is desirable in semiconductor devices. However, when an interconnect has a high resistance the performance of the integrated circuit containing device decreases.

Because of its material properties including high conductivity, molybdenum is a desirable material for multiple applications in semiconductor device manufacturing. However, depositing molybdenum on certain substrate materials is challenging due to the corrosive nature of molybdenum precursors. For example, if molybdenum is to be deposited on a copper containing substrate, the exposure to molybdenum precursors can corrode exposed copper surfaces before the molybdenum is deposited thereon which creates corrosion products that are incorporated into the deposited layer and will adversely affect the performance of the formed interconnect.

Accordingly, there is a need in the art for improved molybdenum deposition processes.

### SUMMARY

In an embodiment, the present disclosure generally provides methods. The methods include metal gap fill deposition on a semiconductor substrate. The methods include forming a liner layer on a surface of a feature by providing a first dosage and a second dosage of a first metal-containing precursor to a processing chamber. The feature includes a feature formed in a surface of the semiconductor substrate. The feature includes an opening that is defined by a capping layer and side walls. The side walls include a dielectric material. The liner layer is formed over the side walls and the capping layer. A metal gap fill material is deposited over the liner layer to fill the feature formed in the surface of the semiconductor substrate by providing a second metal-containing precursor and a hydrogen-containing precursor to the processing chamber.

In an embodiment, the present disclosure generally provides methods. The methods include metal gap fill deposition on a semiconductor substrate. The methods include forming a liner layer on a surface of a feature by providing a first dosage and a second dosage of a first metal-containing precursor including molybdenum oxychloride to a processing chamber. The feature includes a feature formed in a surface of the semiconductor substrate. The feature includes an opening that is defined by a capping layer and side walls. The side walls include a dielectric material. The liner layer is formed over the side walls and the capping layer. A metal gap fill material is deposited over the liner layer to fill the feature formed in the surface of the semiconductor substrate by providing a second metal-containing precursor including molybdenum chloride and a hydrogen-containing precursor including H₂ to the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a flow chart of a method of metal gap fill deposition process, according to embodiments of the present disclosure.

FIGS. 2A-2E are cross-sectional views of a portion of a semiconductor substrate based on the method of FIG. 2, according to embodiments of the present disclosure.

FIG. 3 is a diagrammatic view of an integrated tool, according to embodiments of the present disclosure.

FIG. 4 illustrates a graphical representation of a gap fill growth and/or etch regime, according to embodiments of the present disclosure

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to gap fill deposition processes. More specifically, embodiments of the present disclosure relate to molybdenum gap fill deposition processes. In some embodiments, a substrate is disposed in a processing chamber such as a chemical vapor deposition (CVD) processing chamber, physical vapor deposition (PVD) processing chamber, an atomic layer deposition (ALD) processing chamber, or another type of processing chamber. A plurality of damascene structures are formed in a surface of the substrate. In some embodiments, the damascene structures are single damascene structures. In other embodiments, the damascene structures are dual damascene structures.

The damascene structures include vias and trenches into which one or more metal layers are deposited. The vias and trenches are formed over an underlying interconnect layer, which comprises a conductive material such as a metal layer. In one or more embodiments, the underlying interconnect layer comprises a copper layer.

A liner layer is formed on the underlying interconnect layer without damaging the material within the underlying interconnect layer. The liner layer can provide a barrier from a gap fill precursor material, e.g., a molybdenum precursor material, to prevent oxidation and/or corrosion of the underlying interconnect layer material, e.g., copper. A gap fill material is then deposited on the liner layer within the vias and trenches of the damascene structures formed in the surface of the substrate. Due to the various methods described herein, advantageously, the liner layer and subsequent gap fill material, e.g., molybdenum, can be used to form vias and/or small and high-aspect ratio interconnect features, thereby reducing resistivity of the feature in the device. Additionally, and without being bound by theory, the gap fill material may be selective towards a bottom surface of the feature, e.g., the cavity, via, and/or trench, thereby reducing resistivity by preventing seam formation within the gap fill material disposed within the via and/or interconnect features.

### Processing Examples

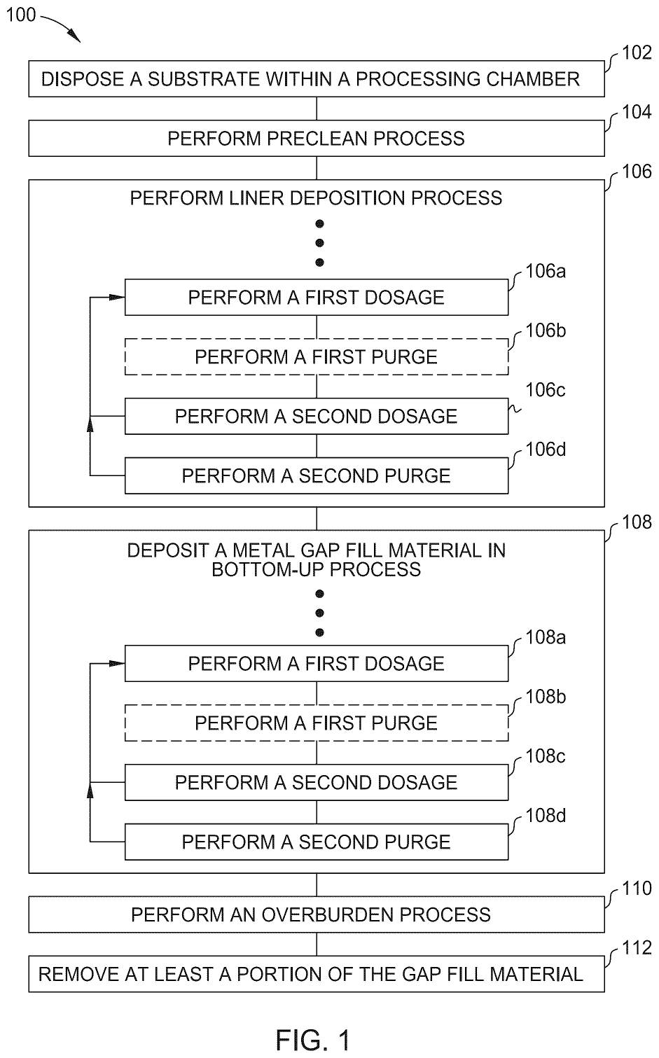

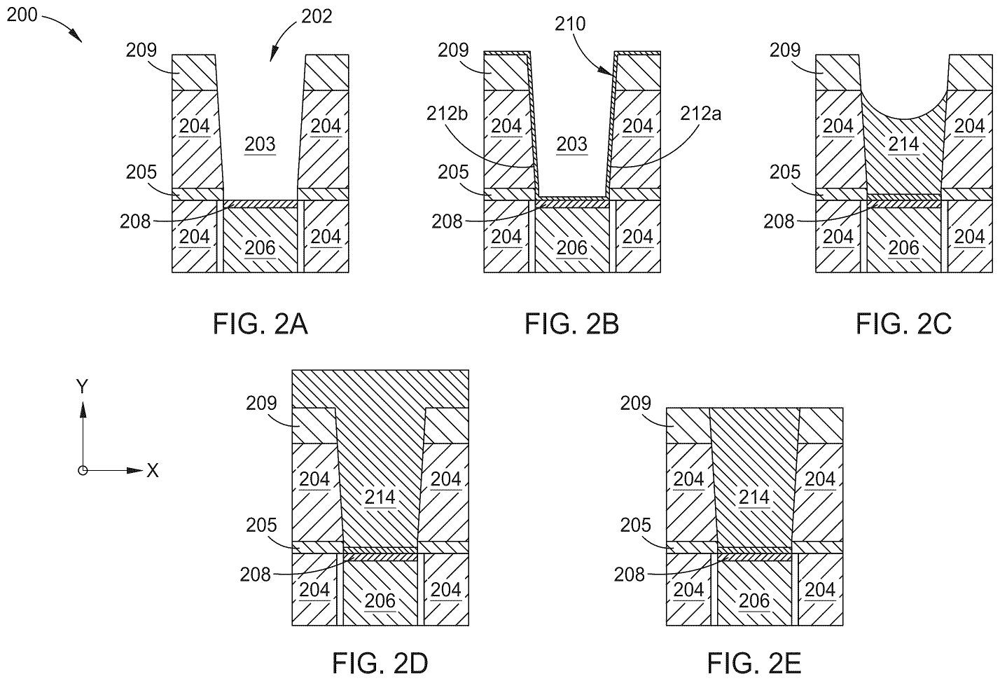

The methods of the present disclosure can be effective for metal gap fill processes in general and may be used with other metal gap fill material besides molybdenum (Mo) such as, for example, tungsten (W) and the like. For the sake of brevity, examples discussed herein include gap fill processes that include molybdenum which are not meant to be limit the scope of the disclosure provided herein and thus can include materials other than molybdenum. In the method 100 of FIG. 1, a method of metal gap fill is shown. In the discussion of the method 100, references will be made to FIGS. 2A-2E. At operation 102, a substrate 200 is disposed within a processing chamber, the substrate having a plurality of damascene structures 202 formed in a surface of the substrate. The damascene structures 202 extend into the substrate in the Z-direction with features formed within the substrate in the X-direction and the Y-direction. In some embodiments, the damascene structures 402 are dual damascene structures. In other embodiments, the damascene structures 402 are single damascene structures.

The damascene structures 202 each include a feature, e.g., a trench, a cavity, a via, or a combination thereof. For example, as shown in FIG. 2A, the damascene structures 202 can include a cavity 203 of a substrate 204 formed of a dielectric material (e.g., silicon dioxide, silicon nitride, etc.). In some embodiments, the materials at the surface of the cavity 203 may be a silicon material or a silicon germanium (SiGe) material.

In one or more embodiments, cavities (e.g., vias, trenches, etc.) can have an average width. For example, the cavity 203 can have a width (shown in FIG. 2A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavities (e.g., vias) can have an average critical dimension of about 1 nanometer (nm) to about 20 nm, which is typically measured in one direction (e.g., X-direction) at the interface of the opening portion of the cavity 203 and the field region (i.e., top surface) of the substrate. For example, the cavity 203 can have a critical dimension, e.g., a width between a first sidewall 724a and a second sidewall 724b of the features, of about 20 nanometers (nm) or less, such as about 1 nm to about 15 nm, such as about 1 nm, 5 nm, and 10 nm to about 12 nm, 15 nm, or 20 nm. Without being bound by theory, the present methods can allow for the deposition of a gap fill material having no and/or reduced seams within the gap fill material due to the liner layer described herein. In one or more embodiments, cavity 203 can have an aspect ratio (depth:width) of about 1:1 to about 100:1, such as about 10:1, 15:1, or 25:1 to about 35:1, 45:1, or 50:1.

The substrate 204 may be disposed over an etch stopping layer 205. In some embodiments, the damascene structures 202 can include a thin film encapsulation layer 209 disposed over the substrate 204. The thin film encapsulation layer 209 can include a tetraethyl orthosilicate layer and/or a tungsten doped carbide layer.

As shown in FIG. 2A, a layer 206 (e.g., a metal layer) of an underlying interconnect layer is formed below the feature. In some embodiments, the layer 206 includes a copper layer, molybdenum layer, tungsten layer, or a cobalt layer. In other embodiments, the layer 206 includes a layer of another material. A capping layer 208 of the underlying interconnect layer is deposited over the layer 206 below the substrate 204. In one or more embodiments, the capping layer 208 includes a cobalt layer. In some embodiments, the capping layer 208 includes a layer of another material. The capping layer 208 can protect the layer 206 from oxidation during the processes of the present disclosure, thereby reducing resistivity of the contact formation.

At operation 104, as shown in FIG. 2A, a preclean process is performed to remove any contaminates and/or oxidation from surfaces of the feature. At operation 106, a liner deposition process is performed to produce a liner layer 210, such as a molybdenum containing layer and/or a tungsten containing layer, on the first sidewall 224a, the second sidewall 224b, and the capping layer 208, as depicted in FIG. 2B. For example, the liner layer 210 can include a molybdenum layer and/or a tungsten layer. The process includes depositing the liner layer 210 over the dielectric material of the substrate 204. In some embodiments, the deposition process is a chemical vapor deposition (CVD) process, an atomic layer deposition (ALD) process, or a molecular layer deposition (MLD) process. In some embodiments, the deposition process is a plasma enhanced process, e.g., a plasma enhanced ALD process (PEALD) and/or a plasma enhanced MLD process (PEMLD). The liner deposition process can provide a thickness of liner layer 210 of about 5 Å to about 100 Å on the first sidewall 212a, the second sidewall 212b, and/or the capping layer 208. In some embodiments, the thickness of the liner layer 210 is conformal along the first sidewall 212a, the second sidewall 212b, and the capping layer 208.

The liner deposition process can be performed using any suitable thermal or plasma enhanced ALD or MLD process. In some embodiments, the ALD or MLD process includes utilizing a plasma that includes metal containing precursors, e.g., molybdenum containing precursors and/or tungsten containing precursors. A carrier gas may be utilized in the CVD or ALD process. The plasma/carrier gas may then be introduced towards the surface of the semiconductor substrate. In one or more embodiments, the carrier gas includes a noble gas, such as argon, neon, helium, or combinations thereof. In one or more embodiments, a capacitively coupled plasma (CCP) deposition process may be used for the PEALD and/or PEMLD.

In one or more embodiments, deposition includes introducing a metal-containing precursor with the carrier gas to the processing chamber. In one or more embodiments, the metal-containing precursor gas may be a molybdenum containing precursor, e.g., molybdenum oxychloride (MoO₂Cl₂). At operation 106a, a first dosage of the liner deposition process is performed. The first dosage of the liner deposition process includes introducing the metal-containing precursor for a first period of time of about 0.5 seconds(s) to about 3.0 s, e.g., such as about 0.5 s, 0.75 s, and 1.0 s to about 2.0 s, 2.5 s, and about 3.0 s. The first dosage of the liner deposition process includes introducing the metal-containing precursor to the processing chamber at a temperature of about 200° C. to about 400° C. The first dosage of the liner deposition process includes introducing the metal-containing precursor to the processing chamber at a pressure of about 0.5 Torr to about 20 Torr. The first dosage of the liner deposition process includes introducing the metal-containing precursor to the processing chamber at a flow rate of about 100 sccm to about 3000 sccm.

Without being bound by theory the first dosage of the liner deposition process can advantageously produce a single conformal mono-layer of the liner layer 210 due to process conformality.

At operation 106b, a first purge of the liner deposition process is performed. The first purge of the liner deposition process includes introducing a purge gas, e.g., a carrier gas and/or an inert gas to the processing chamber following the first dosage of the liner deposition process. The first purge of the liner deposition process may occur for a second period of time of about 1.0 seconds(s) to about 2.0 s, e.g., such as about 1.0 s to about 1.5 s.

The first purge of the liner deposition process includes introducing the metal-containing precursor to the processing chamber at a temperature of about 200° C. to about 400° C. The first purge of the liner deposition process includes introducing the metal-containing precursor to the processing chamber at a pressure of about 0.5 Torr to about 20 Torr. The first purge of the liner deposition process includes introducing the metal-containing precursor to the processing chamber at a flow rate of about 0 sccm to about 3000 sccm. The first purge of the liner deposition process can include introducing H₂ at a flow rate from 0 sccm to 30,000 sccm.

At operation 106c, a second dosage of the liner deposition process is performed. The second dosage of the liner deposition process includes introducing the metal-containing precursor or reactant (H₂) for a third period of time of about 1.0 seconds(s) to about 4.0 s, e.g., such as about 1.0 s to about 2.0 s, 3.0 s, and about 4.0 s. The second dosage of the liner deposition process includes introducing the metal-containing precursor to the processing chamber at a temperature of about 200° C. to about 400° C. The second dosage of the liner deposition process includes introducing the metal-containing precursor to the processing chamber at a pressure of about 0.5 Torr to about 20 Torr. The second dosage of the liner deposition process includes introducing the metal-containing precursor to the processing chamber at a flow rate of about 0 sccm to about 3000 sccm. The second dosage of the liner deposition process can include introducing H₂ at a flow rate from 0 sccm to 30,000 sccm.

The second dosage of the liner deposition process can include introducing an amount of the metal-containing precursor using any suitable thermal or plasma enhanced ALD or MLD process. The plasma enhanced ALD or MLD process can include a plasma power of about 100 W to about 600 W, e.g., about 100 W to about 550 W, about 150 W to about 550 W, about 200 W to about 500 W, or about 300 W to about 450 W. Without being bound by theory, the thermal or plasma enhanced ALD or MLD process can advantageously provide an enhanced deposition rate, while reducing and/or removing impurities formed during the deposition process.

In some embodiments, the second dosage of the liner deposition process may occur after the first dosage of the liner deposition process and/or after the first purge of the liner deposition process. At operation 106d, a second purge of the liner deposition process is performed. The second purge of the liner deposition process includes introducing a purge gas, e.g., the carrier gas and/or an inert gas to the processing chamber following the second dosage. The second purge of the liner deposition process may occur for a fourth period of time of about 1.0 seconds(s) to about 2.0 s, e.g., such as about 1.0 s to about 1.5 s. The second purge of the liner deposition process includes introducing the metal-containing precursor to the processing chamber at a temperature of about 200° C. to about 400° C. The second purge of the liner deposition process includes introducing the metal-containing precursor to the processing chamber at a pressure of about 0.5 Torr to about 20 Torr. The second purge of the liner deposition process includes introducing the metal-containing precursor to the processing chamber at a flow rate of about 0 sccm to about 3000 sccm.

In some embodiments, first dosage of the liner deposition process, second dosage of the liner deposition process, first purge of the liner deposition process, and/or second purge of the liner deposition process may be repeated independently to according to one or more iterative cycles. The one or more iterative cycles can include iteratively repeating a cycle of a first dosage of the liner deposition process and a first purge of the liner deposition process. The one or more iterative cycles can include iteratively repeating a cycle of a first dosage of the liner deposition process, a first purge of the liner deposition process, and a second deposition of the liner deposition process. The one or more iterative cycles can include iteratively repeating a cycle of a first dosage of the liner deposition process, a first purge of the liner deposition process, a second deposition of the liner deposition process, and a second purge of the liner deposition process. The one or more iterative cycles can include iteratively repeating a cycle of a first dosage of the liner deposition process and a second deposition of the liner deposition process. The one or more iterative cycles can include iteratively repeating a cycle of a first dosage of the liner deposition process, a second deposition of the liner deposition process, and a second purge of the liner deposition process. The one or more iterative cycles can be repeated for about 2 cycles to about 100 cycles, e.g. about 2 cycles to about 90 cycles, about 10 cycles to about 80 cycles, about 20 cycles to about 60 cycles, or about 30 cycles to about 50 cycles.

In one or more embodiments, the liner deposition process is performed by maintaining the semiconductor substrate at a first deposition temperature. In one or more embodiments, the semiconductor substrate is maintained at a first deposition temperature of about 250° C. to 400° C., such as about 250° C., 260° C., 270° C., 280° C., and 300° C. to about 325° C., 350° C., and 400° C. In one or more embodiments, the processing chamber is maintained at a pressure of about 1 Torr to about 10 Torr, such as about 1 Torr, about 2 Torr, about 3 Torr, about 4 Torr, and about 5 Torr to about 6 Torr, about 7 Torr, about 8 Torr, about 9 Torr, and about 10 Torr.

In some embodiments, the processing chamber may be maintained at a first pressure during the first deposition of the liner deposition process. In some embodiments, the processing chamber may be maintained at a second pressure during the first purge of the liner deposition process. In some embodiments, the processing chamber may be maintained at a third pressure during the second deposition of the liner deposition process. In some embodiments, the processing chamber may be maintained at a fourth pressure during the second purge of the liner deposition process. In some embodiments, the processing chamber may be maintained at a fifth pressure during the first deposition of the metal gap fill process. In some embodiments, the processing chamber may be maintained at a sixth pressure during the first purge of the metal gap fill process. In some embodiments, the processing chamber may be maintained at a seventh pressure during the second deposition of the metal gap fill process. In some embodiments, the processing chamber may be maintained at an eighth pressure during the second purge of the metal gap fill process. The first pressure, second pressure, third pressure, fourth pressure, fifth pressure, sixth pressure, seventh pressure, and/or eighth pressure may be the same or different.

At operation 108, a metal gap fill material 214 is deposited in a bottom-up deposition process (e.g., molybdenum based deposition process or tungsten based deposition process) over the liner layer 210 after the performance of operation 106, as shown in FIG. 2C. Without being bound by theory, a bottom-selective deposition process can prevent seams from forming in the metal gap fill material, thereby reducing resistance and increasing throughout during manufacturing processes.

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

In some embodiments, a conformal gap fill may be used instead of a bottom-up selective deposition process. In some embodiments, for example, the cavity 203 may be filled by conformal ALD processes using molybdenum or tungsten. In some embodiments, a conformal molybdenum fill can be performed by using MoO₂Cl₂ or MoOCl₄ +H₂ processes or a mixture of MoCl₅ with the aforementioned two precursors. Similarly, the structure fill can be done by a selective W bottom-up fill or conformal W fill process. In some embodiments, Mo and W materials can be interchanged or mixture of Mo and W used.

In an effort to maintain a conformal gap fill process, the bottom-up selective deposition process and/or conformal ALD processes may be performed under conditions of a “soak” type etching process as described herein. The “soak” type etching process may allow for deposition of the gap fill material along the bottom portion of the cavity prior to deposition along the top portion of the side walls. The “soak” type etching processing includes introducing a hydrogen-containing precursor such as molecular hydrogen (H₂) and the metal-containing precursor such as molybdenum chloride (MoCl₅) to the processing chamber concurrently. Without being bound by theory, the introduction of both the hydrogen-containing and the metal-containing precursors into the carrier gas causes both precursors to become energized on a molecular level to a point of at least partial disassociation in the carrier gas. For example, molybdenum chloride may disassociate into molybdenum-based ions (Mo⁺, MoClₓ⁺) or free radial molybdenum trichloride (MoCl₄*); hydrogen may disassociate into hydronium ions (H⁺) or hydrogen free radicals (H*). The dissociated species may then preferentially interact with the gap fill material of the first sidewall 212a, the second sidewall 212b, to etch the gap fill material coupled to the first sidewall 212a, the second sidewall 212b, selectively over the bottom surface. The preferential interaction can be controlled by controlling the substrate process temperature, process pressure, process time, and composition of the process gas that will include the molecular hydrogen (H₂) and the metal-containing precursor (e.g., MoCl₅).

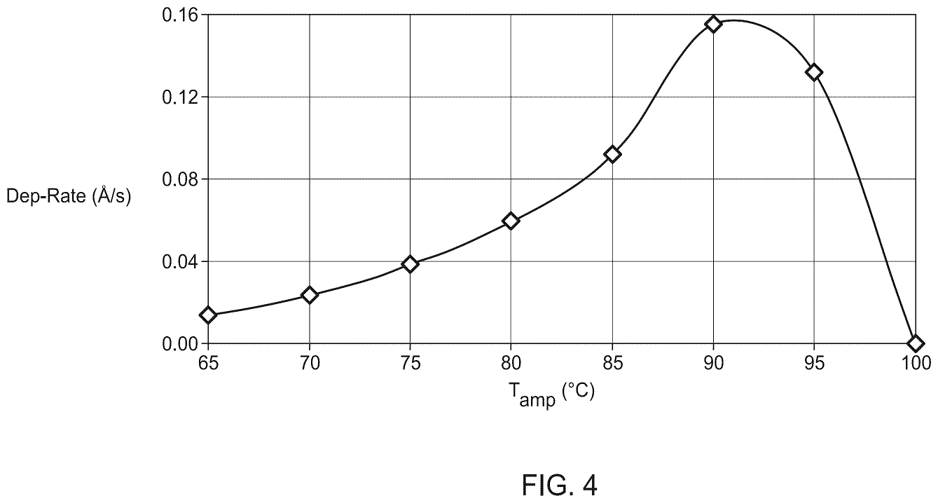

Growth versus etch amounts of a metal gap fill material may be controlled according to an ampoule temperature of the metal-containing precursor. The metal-containing precursor can be about 65° C. to about 100° C. while a fixed carrier gas and hydrogen gas are introduced into the chamber according to a flow rate of about 1 sccm to about 3000 sccm, as described in further detail below, referring to FIG. 4. The ampoule temperature can be correlated, e.g., directly, to the mass flow rate of the metal-containing precursor that enters the processing chamber. In some embodiments, ampoule temperature of about 60° C. to about 120° C. may result in molybdenum growth processes, e.g., due to the hydrogen interacting with the MoCl₅ such that molybdenum radicals may preferentially form and adhere to the liner layer 210. For example, a reduced stoichiometric ratio of the MoCl₅ and the hydrogen gas may occur at a bottom portion of the cavity due thereby allowing the hydrogen to react with the MoCl₅ and favor deposition of Mo at the bottom portion of the cavity and/or feature. The reduced stoichiometric ratio of the MoCl₅ and the hydrogen gas can occur due to the reduced diffusion of the MoCl₅, thereby limiting the amount of MoCl₅ at the bottom portion of the cavity and/or feature, and allowing the hydrogen to saturate the MoCl₅ such that radical molybdenum may preferentially deposit along the bottom portion of the cavity.

Alternatively, at ampoule temperatures of greater than 90° C., the metal-containing precursor flow rate may cause the deposition rate of the molybdenum to be reduced due to the increased stoichiometric ratio of the MoCl₅ and the hydrogen gas such that the MoCl₅ may not be saturated by the hydrogen gas, thereby allowing the radicals, molybdenum-based ions (Mo⁺, MoClₓ⁺) or free radial molybdenum trichloride (MoCl₄*) to etch the molybdenum deposited along the one or more sidewalls and/or top surface of the cavity and/or cavity at a greater rate than deposition occurs.

In one or more embodiments, the gap fill process is performed at a pressure of about 3 Torr to about 300 Torr, a pedestal temperature of about 350° C. to about 450° C. In some embodiments, the process can include controlling an ampoule temperature between about 60° C. and about 120° C. so as to control the precursor flow rate, metal concentration in the precursor, and metal-containing precursor dose amount. At operation 108a, a first dosage of the gap fill process is performed. The first dosage of the gap fill process includes introducing a metal-containing precursor, e.g., MoCl₅, to the processing chamber during a fifth period of time, e.g., about 0.3 seconds(s) to about 1.0 s, e.g., such as about 0.3 s, 0.4 s, and 0.5 s to about 0.8 s, 0.9 s, and about 1.0 s. The first dosage can include a pressure of about 10 Torr, a pedestal temperature of about 400° C., and an ampoule temperature of about 100° C. At operation 108b, a first purge of the gap fill process is performed. The first purge of the gap fill process includes introducing a purge gas, e.g., the carrier gas and/or an inert gas to the processing chamber following the first dosage. The first purge may occur for a sixth period of time of about 1.0 seconds(s) to about 2.0 s, e.g., such as about 1.0 s to about 1.5 s. The first purge can include a pressure of about 10 Torr and a pedestal temperature of about 400° C.

At operation 108c, a second dosage of the gap fill process is performed. The second dosage of the gap fill process includes introducing a hydrogen containing precursor, e.g., hydrogen gas, for a seventh period of time of about 1.0 seconds(s) to about 4.0 s, e.g., such as about 1.0 s to about 2.0 s, 3.0 s, and about 4.0 s. The second dosage can include a pressure of about 10 Torr, a pedestal temperature of about 400° C., and a flow rate of H₂ of about 20,000 sccm to about 22,000 sccm. In some embodiments, the second dosage of the gap fill process may occur after the first dosage of the gap fill process and/or after the first purge of the gap fill process. In some embodiments, a ratio of the hydrogen containing precursor of the second dosage of the gap fill process to the metal-containing precursor of the first dosage of the gap fill process may be about 5,000:1 to about 30,000:1 sccm: sccm such as about 20:000:1 sccm: sccm of the hydrogen containing precursor of the second dosage of the gap fill process to the metal-containing precursor of the first dosage of the gap fill process. At operation 108d, a second purge of the gap fill process is performed. The second purge of the gap fill process includes introducing a purge gas, e.g., the carrier gas and/or an inert gas to the processing chamber following the second dosage of the gap fill process. The second purge of the gap fill process may occur for an eighth period of time of about 1.0 seconds(s) to about 2.0 s, e.g., such as about 1.0 s to about 1.5 s.

In some embodiments, first dosage of the gap fill process, second dosage of the gap fill process, first purge of the gap fill process, and/or second purge of the gap fill process may be repeated independently to according to one or more iterative cycles. The one or more iterative cycles can include iteratively repeating a cycle of a first dosage of the gap fill process and a first purge of the gap fill process. Each repeated cycle of the first dosage of the gap fill process and the first purge of the gap fill process may include independent temperatures, ampoule temperatures, and/or pedestal temperatures. For example, a first cycle may include a first dosage having an ampoule temperature of about 60° C. to about 120° C., at a first carrier gas flow rate, to promote growth of the molybdenum gap-fill material, while a second cycle may include a first dosage having an ampoule temperature of about 90° C. or greater, at the same carrier gas flow rate, to etch the molybdenum gap-fill material from the sidewalls and/or top surface of the cavity and/or feature.

The one or more iterative cycles can include iteratively repeating a cycle of a first dosage of the gap fill process, a first purge of the gap fill process, and a second deposition of the gap fill process. The one or more iterative cycles can include iteratively repeating a cycle of a first dosage of the gap fill process, a first purge of the gap fill process, a second deposition of the gap fill process, and a second purge of the gap fill process. The one or more iterative cycles can include iteratively repeating a cycle of a first dosage of the gap fill process and a second deposition of the gap fill process. The one or more iterative cycles can include iteratively repeating a cycle of a first dosage of the gap fill process, a second deposition of the gap fill process, and a second purge of the gap fill process. The one or more iterative cycles can be repeated for about 400 cycles to about 1200 cycles, e.g. about 400 cycles to about 1100 cycles, about 500 cycles to about 1000 cycles, about 600 cycles to about 900 cycles, or about 700 cycles to about 800 cycles. Without being bound by theory, the gap fill process may allow for conformal gap fill process that reduces and/or eliminates seams within the gap fill material.

At operation 110, as shown in FIG. 2D, an overburden process may be performed such that the metal gap fill material 214 fills the cavity 203, and is deposited on a top surface of the thin film encapsulation layer 209. The metal gap fill material 214 may cover the thin film encapsulation layer 209 to provide a thickness of about 100 Å to about 400 Å, such as about 100 Å, about 120 Å, about 140 Å, about 160 Å, about 180 Å, or about 200 Å to about 300 Å, about 320 Å, about 340 Å, about 360 Å, about 380 Å, or about 400 Å. The metal gap fill material 214 is shown in contact with the liner layer 210 disposed over the capping layer 208, the side walls 212a and 212b, and the thin film encapsulation layer 209. Without being bound by theory, by performing a bottom-up deposition process according to operation 108, a reduction of time to achieve the overburden state, e.g., a state in which the gap-fill material extend above a top surface of the feature, may occur by reducing the amount of seams and/or voids within the gap-fill material during the deposition process, thereby reducing and/or eliminating manufacturing pauses to prevent seams and/or voids from forming.

At operation 112, as shown in FIG. 2E, at least a portion of the gap fill material 214 is removed from the top surface of the thin film encapsulation layer 209. The at least a portion of the gap fill material 214 may be removed according to a chemical mechanical polishing (CMP) process. In at least one embodiment, the at least a portion of the gap fill material 214 may be removed such that the gap fill material 214 is planar with the top surface of the thin film encapsulation layer 209.

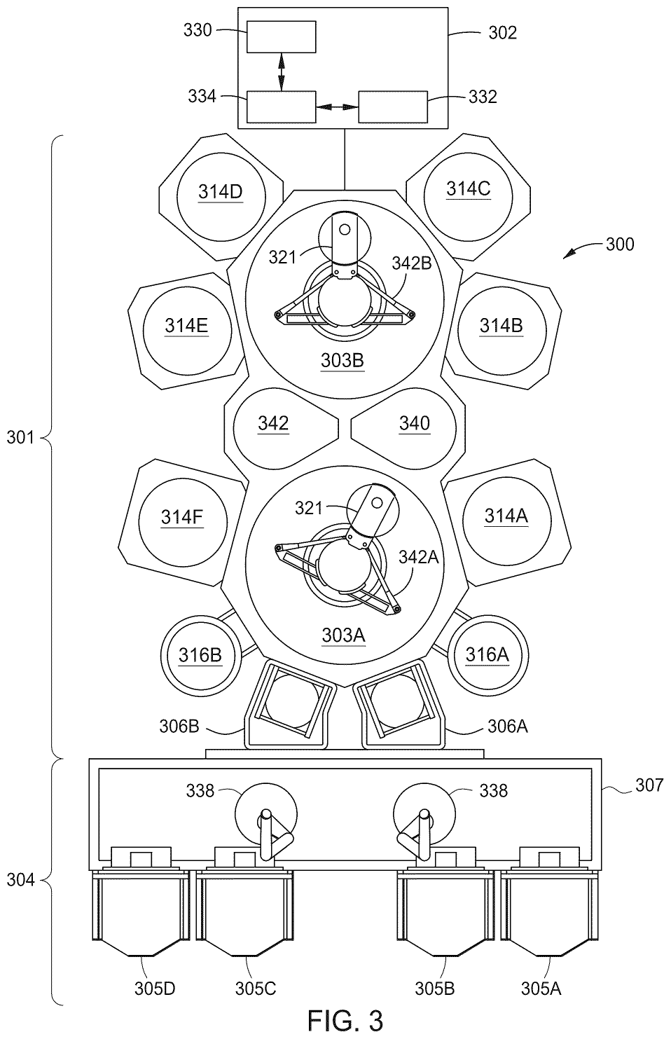

The methods of the present disclosure may be performed in individual process chambers that may be provided as part of a cluster tool, for example, the integrated tool 300 (e.g., cluster tool) described below with respect to FIG. 3. The advantage of using an integrated tool 300 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 300 includes a vacuum-tight processing platform 301, a factory interface 304, and a system controller 302. The vacuum-tight processing platform 301 comprises multiple processing chambers, such as 314A, 313B, 314C, 314D, 314E, and 314F operatively coupled to a vacuum substrate transfer chamber (transfer chambers 303A, 303B). The factory interface 304 is operatively coupled to the transfer chamber 303A by one or more load lock chambers (two load lock chambers, such as 306A and 306B shown in FIG. 3).

In some embodiments, the factory interface 304 comprises at least one docking station 307, at least one factory interface robot 338 to facilitate the transfer of the semiconductor substrates. The docking station 307 is configured to accept one or more front opening unified pod (FOUP). Four FOUPS, such as 305A, 305B, 305C, and 305D are shown in the embodiment of FIG. 3. The factory interface robot 338 is configured to transfer the substrates from the factory interface 304 to the vacuum-tight processing platform 301 through the load lock chambers, such as 306A and 306B. Each of the load lock chambers 306A and 306B have a first port coupled to the factory interface 304 and a second port coupled to the transfer chamber 303A. The load lock chamber 306A and 306B are coupled to a pressure control system (not shown) which pumps down and vents the load lock chambers 306A and 306B to facilitate passing the substrates between the vacuum environment of the transfer chamber 303A and the substantially ambient (e.g., atmospheric) environment of the factory interface 304. The transfer chambers 303A, 303B have vacuum robots 342A, 342B disposed in the respective transfer chambers 303A, 303B. The vacuum robot 342A is capable of transferring substrates 321 between the load lock chamber 306A, 306B, the processing chambers 314A and 314F and a cooldown station 340 or a pre-clean station 342. The vacuum robot 342B is capable of transferring substrates 321 between the cooldown station 340 or pre-clean station 342 and the processing chambers 314B, 314C, 314D, and 314E.

In some embodiments, the processing chambers 314A, 314B, 314C, 314D, 314E, and 314F are coupled to the transfer chambers 303A, 303B. The processing chambers 314A, 314B, 314C, 314D, 314E, and 314F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 316A and 316B) may be coupled to the transfer chamber 303A. The service chambers 316A and 316B may be configured to perform other substrate processes, such as degassing, orientation, substrate metrology, cool down, and the like.

The processing chambers 320, 322, 324, 326, 328, 330 may be any appropriate chamber for processing a substrate. In some examples, a processing chamber may be capable of performing an etch process, a cleaning process, an annealing process, a CVD deposition process, or an ALD deposition process. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 302 controls the operation of the tool 300 using a direct control of the process chambers 314A, 314B, 314C, 314D, 314E, and 314F or alternatively, by controlling the computers (or controllers) associated with the process chambers 314A, 314B, 314C, 314D, 314E, and 314F and the tool 300. In operation, the system controller 302 enables data collection and feedback from the respective chambers and systems to optimize performance of the tool 300. The system controller 302 generally includes a Central Processing Unit (CPU) 330, a memory 334, and a support circuit 332. The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as a method as described above may be stored in the memory 334 and, when executed by the CPU 330, transform the CPU 330 into a specific purpose computer (system controller). The software routines may also be stored and/or executed by a second controller (not shown) that is located remotely from the tool 300. The integrated tool 300 hardware, CPU 330 and software routines are configured to work together to perform one or more of the methods and processes described herein.

### EXAMPLES

### Example 1

Growth versus etch amounts of a metal gap fill material, e.g., molybdenum deposition process were determined when using MoCl₅ as an precursor gas, as shown in FIG. 4. The etching process was performed with an ampoule temperature of 65° C. to 100° C. while a fixed carrier gas and hydrogen flow rate were maintained within the chamber. The ampoule temperature was directly correlated to the mass flow rate of the etchant gas entering the processing chamber. Molybdenum resulted in a deposition rate of about 0.01 to about 0.16 Å/s when maintaining an ampoule temperature of 65° C. to 90° C. At these temperatures the growth of the molybdenum containing layer within the cavity or feature was uniform, e.g., not selective to a top portion of the cavity and/or a lower portion of the cavity. At ampoule temperatures of greater than 90° C., the metal-containing precursor flow rate at a constant carrier gas and hydrogen flow rate caused the deposition rate of the molybdenum to be reduced due to the reduced stoichiometric ratio of the MoCl₅ and the hydrogen gas being reduced at a bottom portion of the cavity due thereby allowing the hydrogen to react with the MoCl₅ and favor deposition of Mo at the bottom portion of the cavity and/or feature. The reduced stoichiometric ratio of the MoCl₅ and the hydrogen gas can occur due to the reduced diffusion of the MoCl₅, thereby limiting the amount of MoCl₅ at the bottom portion of the cavity and/or feature. Accordingly, a top portion of the cavity had a suppressed growth rate, thereby allowing the bottom portion of the cavity to deposit gap-fill material preferentially compared to the top portion. Without being bound by theory, the top suppressed growth rate can allow for reduced seam formation and reduced resistance within the gap fill material.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

Overall, methods of the present disclosure can provide liner layers formed on an underlying interconnect layer without damaging the material within the underlying interconnect layer. The liner layer can provide a barrier from a gap fill precursor material, e.g., a molybdenum precursor material, to prevent oxidation and/or corrosion of the underlaying interconnect layer material, e.g., copper. Advantageously, the liner layer and subsequent gap fill material, e.g., molybdenum, can allow for reduced dimension vias and/or features to be filled with a gap fill material, thereby reducing resistivity of the feature in the device. Additionally, and without being bound by theory, the gap fill material may be selective towards a bottom surface of the feature, e.g., the cavity, via, and/or trench, thereby reducing resistivity by preventing seam formation within the gap fill material.

While the foregoing is directed to embodiments of the present principles, other and further embodiments of the principles may be devised without departing from the basic scope thereof.

What is claimed is:

1. A method of metal gap fill deposition on a semiconductor substrate, comprising:
forming a liner layer on a surface of a feature by providing a first dosage and a second dosage of a first metal-containing precursor to a processing chamber, wherein:
the feature comprises a feature formed in a surface of the semiconductor substrate,
the feature comprises an opening that is defined by a capping layer and side walls, wherein the side walls comprise a dielectric material, and
the liner layer is formed over the side walls and the capping layer; and
depositing a metal gap fill material over the liner layer to fill the feature formed in the surface of the semiconductor substrate by providing a second metal-containing precursor and a hydrogen-containing precursor to the processing chamber.

2. The method of claim 1, wherein the first dosage comprises introducing the first metal-containing precursor according to a chemical vapor deposition process, an atomic layer deposition process, or a molecular layer deposition process.

3. The method of claim 1, wherein the second dosage comprises introducing the first metal-containing precursor according to a plasma enhanced deposition process.

4. The method of claim 3, wherein the plasma enhanced deposition process comprises a plasma power of about 100 W to about 600 W.

5. The method of claim 1, further comprising providing a first purge between the first dosage and the second dosage.

6. The method of claim 5, further comprising providing a second purge after the second dosage.

7. The method of claim 6, wherein the first dosage, the first purge, the second dosage, and the second purge are repeated for 400 to 1200 cycles.

8. The method of claim 1, wherein the first metal-containing precursor is molybdenum oxychloride.

9. The method of claim 8, wherein the second metal-containing precursor is molybdenum chloride and the hydrogen-containing precursor is H₂.

10. The method of claim 1, wherein the metal gap fill material comprises molybdenum.

11. The method of claim 1, wherein depositing the metal gap fill material comprises depositing the metal gap fill material using an atomic layer deposition process or a chemical vapor deposition process.

12. The method of claim 1, wherein depositing the metal gap fill material comprises:
delivering about 1 sccm to about 3000 sccm of the second metal-containing precursor to the processing chamber for a period of about 0.3 seconds(s) to about 1 second;
delivering a purge gas to the processing chamber for a period of about 1 s to about 2 s;
delivering about 5,000 sccm to about 30,000 sccm of the hydrogen-containing precursor to the processing chamber for a period of about 1 s to about 4 s; and
delivering the purge gas to the processing chamber for a period of about 1 s to about 2 s.

13. The method of claim 12, further comprising repeating delivering the second metal-containing precursor, delivering the purge gas, and delivering the hydrogen-containing precursor for about 400 to 1200 cycles.

14. A method of metal gap fill deposition on a semiconductor substrate, comprising:
forming a liner layer on a surface of a feature by providing a first dosage and a second dosage of a first metal-containing precursor comprising molybdenum oxychloride to a processing chamber, wherein:
the feature comprises a feature formed in a surface of the semiconductor substrate,
the feature comprises an opening that is defined by a capping layer and side walls, wherein the side walls comprise a dielectric material, and
the liner layer is formed over the side walls and the capping layer; and
depositing a metal gap fill material over the liner layer to fill the feature formed in the surface of the semiconductor substrate by providing a second metal-containing precursor comprising molybdenum chloride and a hydrogen-containing precursor comprising H₂ to the processing chamber.

15. The method of claim 14, wherein the first dosage comprises introducing the first metal-containing precursor according to a chemical vapor deposition process, an atomic layer deposition process, or a molecular layer deposition process.

16. The method of claim 14, wherein the second dosage comprises introducing the first metal-containing precursor according to a plasma enhanced deposition process, wherein the plasma enhanced deposition process comprises a plasma power of about 100 W to about 600 W.

17. The method of claim 14, further comprising:
providing a first purge between the first dosage and the second dosage; and
providing a second purge after the second dosage.

18. The method of claim 17, wherein the first dosage, the first purge, the second dosage, and the second purge are repeated for 400 to 1200 cycles.

19. The method of claim 14, wherein depositing the metal gap fill material comprises:
delivering 1 sccm to about 3000 sccm of the second metal-containing precursor to the processing chamber for a period of about 0.3 seconds(s) to about 1 second;
delivering a purge gas to the processing chamber for a period of about 1 s to about 2 s;
delivering about 5,000 sccm to about 30,000 sccm of the hydrogen-containing precursor to the processing chamber for a period of about 1 s to about 4 s; and
delivering the purge gas to the processing chamber for a period of about 1 s to about 2 s.

20. The method of claim 19, further comprising repeating delivering the second metal-containing precursor, delivering the purge gas, and delivering the hydrogen-containing precursor for about 400 to 1200 cycles.
